(19) United States
(12) Patent Application Publication
(10) Pub. No.: US 2025/0125314 A1
(43) Pub. Date: Apr. 17, 2025

(54) INTEGRATION AND CO-PACKAGING OF CONFINEMENT APPARATUS AND APPLICATION-SPECIFIC INTEGRATED CIRCUIT (ASIC) SUBSYSTEM

(71) Applicant: Quantinuum LLC, Broomfield, CO (US)

(72) Inventors: David DEEN, Edinia, MN (US); Matthew SWALLOWS, Broomfield, CO (US); Leonardo ASCARRUNZ, Lafayette, CO (US); Benjamin SPAUN, Westminster, CO (US)

(21) Appl. No.: 18/888,903

(22) Filed: Sep. 18, 2024

Related U.S. Application Data
(60) Provisional application No. 63/590,057, filed on Oct. 13, 2023.

(51) Int. Cl. H01L 25/065; H01L 23/00

(52) U.S. Cl. CPC H01L 25/0657; H01L 24/48; H01L 24/73; H01L 25/0655; H01L 24/16; H01L 2224/16146; H01L 2224/16235; H01L 2224/48225; H01L 2224/73207; H01L 2225/06513; H01L 2225/06517; H01L 2225/06541; H01L 2225/06589; H01L 2924/1433

(57) ABSTRACT

A confinement apparatus package is provided. The confinement apparatus chip includes a confinement apparatus die having a plurality of electrodes formed thereon, wherein the plurality of electrodes defines a confinement apparatus; an application-specific integrated circuit (ASIC) chip comprising an ASIC die having an ASIC formed thereon; and a package substrate. The ASIC die is disposed between the package substrate and the confinement apparatus die. The ASIC defines a plurality of electrical channels and each electrode of the plurality of electrodes is in electrical communication with a respective electrical channel of the plurality of electrical channels.

### CROSS-REFERENCE TO RELATED APPLICATIONS

This application claims priority to U.S. Application No. 63/590,057, filed Oct. 13, 2023, the content of which is incorporated herein by reference in its entirety.

### TECHNICAL FIELD

Various embodiments relate to confinement apparatuses and control systems thereof. For example, an example embodiment relates to a confinement apparatus that is co-packaged with an ASIC configured to control, at least in part, operation of the confinement apparatus.

### BACKGROUND

An ion trap can use a combination of electrical and magnetic fields to capture one or more ions in a potential well. Ions can be trapped for a number of purposes, which may include mass spectrometry, research, and/or controlling quantum states of the trapped ions, for example. For large ion traps, a significant number of electrical connections to the ion trap are used to provide controlling voltage signals to the ion trap. Through applied effort, ingenuity, and innovation many deficiencies of such prior ion traps and ion trap control systems have been solved by developing solutions that are structured in accordance with the embodiments of the present invention, many examples of which are described in detail herein.

### BRIEF SUMMARY OF EXAMPLE EMBODIMENTS

Example embodiments provide confinement apparatus packages, systems including confinement apparatus packages (e.g., quantum charge-coupled device (QCCD)-based quantum computers), and/or the like.

In an example embodiment, a confinement apparatus package includes one or more confinement apparatus chips and one or more application-specific integrated circuit (ASIC) chips. The confinement apparatus chip includes a confinement apparatus die having a plurality of electrodes formed thereon. The plurality of electrodes defines a confinement apparatus. The ASIC defines a plurality of electrical channels with each electrode of the plurality of electrodes formed on the confinement apparatus die being in electrical communication with a respective electrical channel of the plurality of electrical channels. The ASIC chip comprises electronic components (e.g., switches, modulators, phase control elements, delay control elements, and/or the like) configured to control and/or condition voltage signals provided to the plurality of electrodes via the plurality of electrical channels.

According to one aspect, a confinement apparatus package having a 3D architecture is provided. In an example embodiment, the confinement apparatus package includes one or more confinement apparatus dies each having a respective plurality of electrodes formed thereon, wherein the respective pluralities of electrodes define a confinement apparatus; one or more application-specific integrated circuit (ASIC) chips each comprising a respective ASIC die having an ASIC formed thereon; and a package substrate. The one or more ASIC chips are disposed between the package substrate and a respective one of the one or more confinement apparatus dies. The respective ASIC defines a plurality of electrical channels and each electrode of the respective plurality of electrodes is in electrical communication with a respective electrical channel of the plurality of electrical channels.

In an example embodiment, the respective electrical channel comprises at least one shunt capacitor.

In an example embodiment, the at least one shunt capacitor is a trench capacitor.

In an example embodiment, the at least one shunt capacitor is formed one on of (a) the respective confinement apparatus die or (b) the respective ASIC chip.

In an example embodiment, a first portion of the respective electrical channel disposed on the respective ASIC chip is in electrical communication with a second portion of the respective electrical channel disposed on the respective confinement apparatus die, at least in part, via one of (a) a through silicon via (TSV) formed in the respective confinement apparatus die or (b) a wire bond.

In an example embodiment, the confinement apparatus package further includes one or more interposer chips, a respective interposer chip disposed between the respective ASIC chip and the respective confinement apparatus die.

In an example embodiment, the respective electrical channel comprises at least one shunt capacitor and the at least one shunt capacitor is formed on the respective interposer chip.

In an example embodiment, a first portion of the respective electrical channel disposed on the respective ASIC chip is in electrical communication with a third portion of the respective electrical channel disposed on the respective interposer chip, at least in part, via one of (a) a through silicon via (TSV) formed in an interposer die of the respective interposer chip or (b) a wire bond.

In an example embodiment, a third portion of the respective electrical channel disposed on the respective interposer chip is in electrical communication with a second portion of the respective electrical channel disposed on the confinement apparatus die, at least in part, via one of (a) a through silicon via (TSV) formed in an interposer die of the respective interposer chip or (b) a wire bond.

In an example embodiment, a first portion of the respective electrical channel disposed on the respective ASIC chip is configured to condition a voltage signal applied to one or more electrodes of the plurality of electrodes in electrical communication with the respective electrical channel.

In an example embodiment, the package substrate is at least one of a ceramic package or a printed circuit board.

In an example embodiment, a first portion of the respective electrical channel disposed on the respective ASIC chip is in electrical communication with a preliminary portion of the respective electrical channel disposed on the package substrate.

In an example embodiment, the confinement apparatus is a surface ion trap.

According to another aspect, a confinement apparatus package having a 2.5D architecture is provided. In an example embodiment, the confinement apparatus package includes one or more confinement apparatus dies each having a respective plurality of electrodes formed thereon, wherein the respective pluralities of electrodes define a confinement apparatus; one or more ASIC chips each comprising a respective application-specific integrated circuit (ASIC) die having a respective ASIC formed thereon; at least one interposer chip; and a package substrate. The at least one interposer chip is disposed between the respective ASIC chip and the package substrate. The at least one interposer chip is disposed between the respective confinement apparatus die and the package substrate. The respective ASIC defines a plurality of electrical channels and each electrode of the respective plurality of electrodes is in electrical communication with a respective electrical channel of the plurality of electrical channels.

In an example embodiment, the respective confinement apparatus die and the respective ASIC chip are laterally arranged with respect to one another.

In an example embodiment, the confinement apparatus package further includes one or more shunt capacitor chips each comprising a respective plurality of shunt capacitors formed on a respective shunt capacitor die, wherein the at least one interposer chip is disposed between the respective shunt capacitor chip and the package substrate.

In an example embodiment, each shunt capacitor of the respective plurality of shunt capacitors is part of a respective channel of the plurality of electrical channels.

In an example embodiment, at least one shunt capacitor of the respective plurality of shunt capacitors is a trench capacitor.

In an example embodiment, each of the respective confinement apparatus die, the respective ASIC chip, and the respective shunt capacitor chip are laterally arranged with respect to one another.

In an example embodiment, the respective shunt capacitor chip is flip chip mounted to the at least one interposer chip.

In an example embodiment, the respective ASIC chip is flip chip mounted to at least one interposer chip.

In an example embodiment, the confinement apparatus package further includes a backside cooler disposed on an exposed surface of the respective ASIC die, wherein the backside cooler is configured to cool the respective ASIC chip.

In an example embodiment, a first portion of the respective electrical channel disposed on the respective ASIC chip is in electrical communication with a third portion of the respective electrical channel disposed on the respective shunt capacitor chip via the at least one interposer chip.

In an example embodiment, a third portion of the respective electrical channel disposed on the respective shunt capacitor chip is in electrical communication with a second portion of the respective electrical channel disposed on the respective confinement apparatus die, at least in part, via at least one of (a) the at least one interposer chip or (b) a through-silicon-via (TSV) formed in the respective confinement apparatus die.

In an example embodiment, a first portion of the respective electrical channel disposed on the respective ASIC chip is in electrical communication with a second portion of the respective electrical channel disposed on the respective confinement apparatus die, at least in part, via a through silicon via (TSV) formed in the respective confinement apparatus die.

In an example embodiment, a first portion of the respective electrical channel disposed on the respective ASIC chip is configured to condition a voltage signal applied to one or more electrodes of the respective plurality of electrodes in electrical communication with the respective electrical channel.

In an example embodiment, the package substrate is at least one of a ceramic package or a printed circuit board.

In an example embodiment, a first portion of the respective electrical channel disposed on the respective ASIC die is in electrical communication a preliminary portion of the respective electrical channel disposed on the package substrate.

In an example embodiment, the confinement apparatus is a surface ion trap.

According to another aspect, a system comprising a confinement apparatus package having 3D or 2.5D architecture of an example embodiment is provided.

In an example embodiment, the system further includes a cryogenic and/or vacuum chamber, wherein the confinement apparatus package is disposed within the cryogenic and/or vacuum chamber.

In an example embodiment, the system is a QCCD-based quantum computer.

In an example embodiment, the system further includes one or more voltage sources in electrical communication with respective channels of the respective plurality of electrical channels.

In an example embodiment, the system further includes a controller configured to control operation of the one or more voltage sources.

In an example embodiment, the system further includes a controller configured to control one or more switches of the respective ASIC.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 provides a cross-sectional view of an example confinement apparatus package, in accordance with an example embodiment.

FIG. 2 provides a top view of an example confinement apparatus, in accordance with an example embodiment.

FIG. 3A provides a cross-sectional view of another example confinement apparatus package, in accordance with an example embodiment.

FIG. 3B provides a cross-sectional view of another example confinement apparatus package, in accordance with an example embodiment.

FIG. 4 provides a cross-sectional view of another example confinement apparatus package, in accordance with an example embodiment.

FIGS. 5A, 5B, and 5C each illustrate an example electrical channel of a respective example confinement apparatus package, in accordance with various embodiments.

FIG. 6 provides a schematic diagram of an example system including a confinement apparatus package, in accordance with an example embodiment.

FIG. 7 provides a schematic diagram of an example controller of a quantum computer comprising a confinement apparatus package, in accordance with an example embodiment.

FIG. 8 provides a schematic diagram of an example computing entity of a quantum computer system that may be used in accordance with an example embodiment.

### DETAILED DESCRIPTION OF SOME EXAMPLE EMBODIMENTS

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally” and “approximately” refer to within engineering and/or manufacturing limits/tolerances and/or within user measurement capabilities, unless otherwise indicated. Like numbers refer to like elements throughout.

### General Overview

Various embodiments provide confinement apparatus packages that are packaged with three-dimensional (3D) or two and a half-dimensional (2.5D) architecture with an ASIC. In an example embodiment, the confinement apparatus package includes a confinement apparatus chip. The confinement apparatus chip includes a confinement apparatus die having a plurality of electrodes formed thereon. The plurality of electrodes defines a confinement apparatus. In an example embodiment, the confinement apparatus is a surface confinement apparatus, such as a surface ion trap (e.g., a surface Paul trap). For example, the confinement apparatus is configured to trap and/or confine atomic objects such as atoms, ions, molecules, and/or the like and/or groups or crystals thereof.

In an example embodiment, the confinement apparatus chip may include one or more functional layers. For example, the one or more functional layers may be disposed between the confinement apparatus die and the plurality of electrodes and include electrical components (e.g., capacitors such as shunt capacitors and/or trench capacitors, modulators, signal splitters, signal combiners, signal filters, integrated circuits configured to generate microwave fields or signals, and/or the like), optical components (e.g., waveguides, couplers, gratings, metasurfaces, refractive and/or diffractive optics, multiplexers, demultiplexers, beam splitters, beam combiners, modulators, amplifiers, lasers, and/or the like), dielectric components (e.g., for electrically and/or optically isolating the plurality of electrodes and/or other components of the confinement apparatus, and/or the like), and/or other functional components.

In various embodiments, the confinement apparatus package includes an ASIC chip. The ASIC chip is a semiconductor-based chip having an ASIC formed thereon. An ASIC chip is an integrated circuit chip customized for a particular use or application. For example, the ASIC includes electrical components arranged in circuit portions configured to perform application-specific functions. In an example embodiment, the electrical components of the ASIC include capacitors such as shunt capacitors and/or trench capacitors. In various embodiments, the ASIC defines a plurality of electrical channels. Each of the plurality of electrodes of the confinement apparatus chip are in communication with a respective channel of the plurality of electrical channels. Respective circuit portions of the ASIC are configured to control and/or condition voltage signals provided to the plurality of electrodes via respective channels of the plurality of electrical channels.

In various embodiments, the confinement apparatus package is part of a system. For example, the system may be an atomic system, QCCD-based quantum computer, and/or other system that uses a confinement apparatus to trap and/or confine atomic objects such that experiments may be performed on the atomic objects, evolution of the quantum states of the atomic objects may be controlled, and/or the like. In various such systems, the confinement apparatus package is disposed within a cryogenic and/or vacuum chamber. For example, the cryogenic and/or vacuum chamber is configured to control the temperature and/or pressure in the environment around the confinement apparatus package. Electrical and/or voltage signals are passed to the confinement apparatus through the housing of the cryogenic and/or vacuum chamber.

In various embodiments, the confinement apparatus includes a large number of electrodes and/or electrical channels. In systems including conventional confinement apparatuses, the controlling and/or conditioning of the electrical and/or voltage signals provided the electrodes of the confinement apparatus are performed outside of the cryogenic and/or vacuum chamber, resulting in a large number of electrical and/or voltage signals that need to be passed through the housing of the cryogenic and/or vacuum chamber. Additionally, providing electrical connections for the large number of wire bonds required to connect the large number of electrical and/or voltage signals to the respective electrodes requires a significant amount of space on the chip housing the confinement apparatus. Therefore, technical problems exist regarding how to control, condition, and provide electrical and/or voltage signals to electrodes of a confinement apparatus. These technical problems are particularly challenging for large confinement apparatuses (e.g., configured to trap and/or confine 100 atomic objects or more). For example, a large confinement apparatus may include eight thousand electrodes or more.

Various embodiments provide technical solutions to these technical challenges. Various embodiments provide confinement apparatus packages that include an ASIC chip and a confinement apparatus chip. The ASIC chip comprises circuit portions configured to control and/or condition the electrical and/or voltage signals provided to the electrodes of the confinement apparatus. In various embodiments, the ASIC chip defines a plurality of electrical channels with each electrode of the confinement apparatus in electrical communication with a respective electrical channel of the plurality of electrical channels. In various embodiments, the plurality of electrical channels defined by the ASIC chip is a first number of electrical channels and the ASIC chip is configured to receive a second number of electrical and/or voltage signals.

The ASIC provides appropriate electrical and/or voltage signals to respective electrodes via respective ones of the first number of electrical channels based on the received second number of electrical and/or voltage signals, where the first number is greater than the second number. For example, in an example embodiment, the confinement apparatus comprises eight thousand electrodes. However, providing eight thousand independent electrical and/or voltage signals to the interior of a cryogenic and/or vacuum chamber would be technically complicated. Moreover, the surface area of a confinement apparatus package needed to connect eight thousand electrical connections to the confinement apparatus package would be quite large and would lead to additional technical challenges. Various embodiments provide technical solutions to such technical problems by configuring the ASIC to split a received electrical and/or voltage signal (e.g., received via a package substrate in an example embodiment) and cause independently conditioned versions of the split electrical and/or voltage signals to respective electrodes in electrical communication with respective electrical channels. An example of independently conditioning versions of a split electrical and/or voltage signal in an electrical channel specific manner is described by U.S. Application No. 63,583,629, filed Sep. 19, 2023, the contents of which are incorporated herein by reference. Thus, the ASIC chip enables fewer electrical and/or voltage signals to be passed through the housing of the cryogenic and/or vacuum chamber while enabling individual control of the electric and/or voltage signals provided to respective electrodes via the respective electrical channels. Various embodiments therefore provide improvements to the technical fields of confinement apparatus control and/or operation and systems including confinement apparatuses.

In various scenarios, including the controlling and/or conditioning circuit portions of the ASIC results in additional technical challenges. For example, the controlling and/or conditioning circuit portions of the ASIC may cause charge injection and/or electrical transients to be provided to one or more electrodes of the confinement apparatus that are in electrical communication with a respective electrical channel. In various embodiments, this technical challenge is addressed through the inclusion of shunt capacitors in the respective electrical channels.

An additional technical challenge introduced by including the controlling and/or conditioning circuit portions of the ASIC in close proximity to the confinement apparatus chip is the heating caused by operation of the ASIC. In various embodiments, thermal and/or heat slugs are disposed in the ASIC chip, interposer chip, and/or package substrate to transport heat generated by the operation of the ASIC away from the confinement apparatus chip. In another example, the ASIC chip is flip chip mounted to an interposer chip such that a backside cooler can be operatively secured to the backside of the ASIC chip. Therefore, various embodiments provide technical solutions to technical problems that arise in the inclusion the ASIC chip in the confinement apparatus package.

### Example Confinement Apparatus Packages

In various embodiments, a confinement apparatus package includes a confinement apparatus chip and an ASIC chip that have been packaged together in a 3D or 2.5D architecture. In various embodiments, the confinement apparatus package further includes a package substrate. In various embodiments, the ASIC chip is disposed between the confinement apparatus chip and the package substrate. In various embodiments, the package substrate is a ceramic package, printed circuit board, and/or the like.

In various embodiments, the confinement apparatus package includes an interposer chip. In various embodiments, the interposer chip is electrically positioned between the ASIC chip and the confinement apparatus.

In various embodiments, the confinement apparatus package includes a shunt capacitor chip. In various embodiments, the shunt capacitor chip is a chip configured to house at least one shunt capacitor for each electrical channel defined by the ASIC chip. In various embodiments, the shunt capacitors formed on the shunt capacitor chip are trench capacitors.

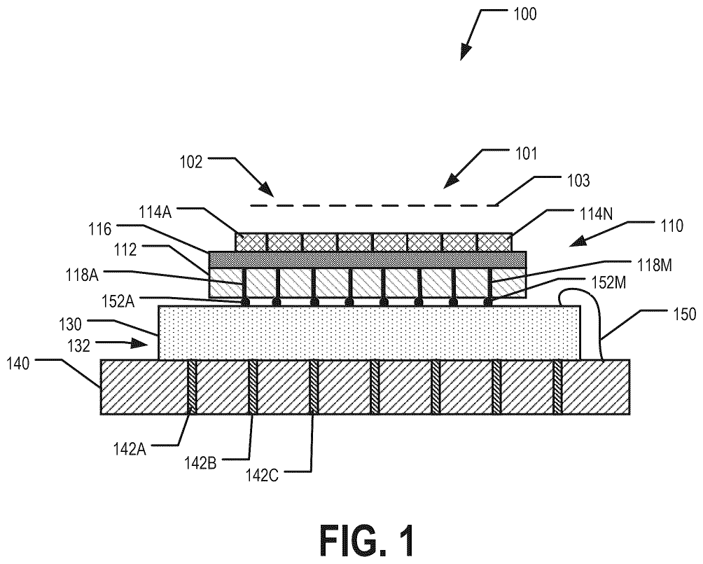

FIG. 1 illustrates an example confinement apparatus package 100 according to an example embodiment. The confinement apparatus package 100 includes a package substrate 140, an ASIC chip 130, and a confinement apparatus chip 110. The ASIC chip 130 is disposed between the package substrate 140 and the confinement apparatus chip 110.

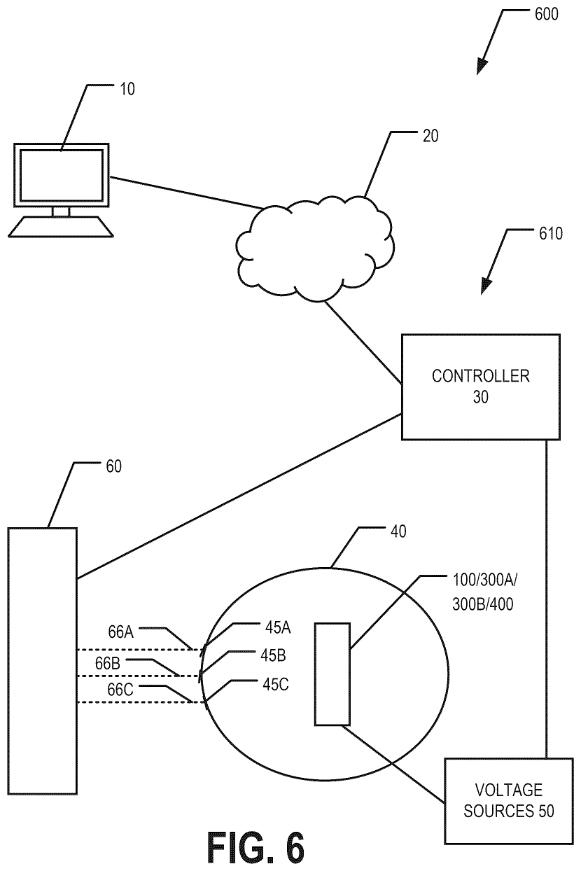

In various embodiments, the package substrate 140 is a ceramic package, printed circuit board, and/or the like. In various embodiments, the package substrate 140 is configured to act as a handle of the confinement apparatus package 100. In various embodiments, the package substrate 140 is configured to receive a plurality of electrical and/or voltage signals that were generated externally (e.g., by voltage sources 50 in FIG. 6). The package substrate 140 may receive the plurality of electrical and/or voltage signals via edge wire bonds, through-silicon-vias (TSVs), and/or the like. In an example embodiment, the package substrate 140 is configured to be mounted in a seat or socket configured to align electrical connection points of the package substrate 140 with electrical connection points of the seat or socket such that the externally generated electrical signals and/or voltage signal are provided to the package substrate 140.

In the illustrated embodiment, the package substrate 140 includes one or more thermal and/or heat slugs 142 (e.g., 142A, 142B, 142C). In an example embodiment, package substrate 140 includes one thermal and/or heat slug 142 that is a brick or block of thermally conductive material that is braced into the ceramic chip carrier, for example, of the package substrate 140. In various embodiments, the one or more thermal and/or heat slugs 142 are formed of a thermally conductive material (e.g., silver, copper, gold, aluminum nitride, silicon carbide, aluminum, tungsten, graphite, zinc, and/or the like). The one or more thermal and/or heat slugs 142 are configured to conduct heat generated through operation of the ASIC 132 away from the confinement apparatus chip 110. In an example embodiment, the one or more thermal and/or heat slugs 142 may be present in the ASIC chip 130 in addition and/or instead of the one or more thermal and/or heat slugs 142 being present in the package substrate 140.

In various embodiments, the ASIC chip 130 comprises an ASIC 132. The ASIC includes electrical components arranged in circuit portions configured to perform application-specific functions. In an example embodiment, the electrical components of the ASIC include capacitors such as shunt capacitors and/or trench capacitors, modulators, signal splitters, signal combiners, amplifiers, phase control elements, delay elements, and/or the like. In an example embodiment, the ASIC 132 formed on the ASIC chip 130 includes shunt capacitors that are coupled to and/or part of respective channels of the plurality of electrical channels.

In various embodiments, the ASIC 132 defines a plurality of electrical channels. For example, the ASIC receives electrical and/or voltage signals from the package substrate 140 via a plurality of wire bonds 150. The ASIC 132 may split and/or combine the received electrical and/or voltage signals to generate channel-specific electrical and/or voltage signals to be provided to respective channels of the plurality of electrical channels. For example, the ASIC 132 may include a plurality of (analog) switches, multiplexers, demultiplexers, and/or the like, in various embodiments. For example, the number of electrical and/or voltage signals provided to the ASIC 132 is fewer than the number of electrical channels defined by the ASIC 132. The ASIC 132 may then condition one or more respective aspects (e.g., amplitude, phase, noise profile (e.g., via filtering), and/or the like) of the channel-specific electrical and/or voltage signal of each respective channel of the plurality of electrical channels. For example, in various embodiments, the ASIC 132 may further include one or more amplitude and/or phase modulators, amplifiers, filters, and/or the like.

In various embodiments, the ASIC chip 130 may also be configured to perform the function of an interposer. For example, in various embodiments, the ASIC chip 130 is configured to be an electrical interface for routing the voltage signals of the respective channels of the plurality of electrical channels from the preliminary portion of the respective channel formed on the package substrate 140 to the second portion of the respective channel formed on the confinement apparatus chip 110 via a first portion of the respective channel formed on the ASIC chip 130.

The confinement apparatus chip 110 comprises a confinement apparatus die 112 and a plurality of electrodes 114 (e.g., 114A, 114N) formed thereon. Each of the plurality of electrodes 114 of the confinement apparatus chip 110 are in communication with a respective channel of the plurality of electrical channels. For example, in various embodiments, the confinement apparatus die 112 includes a plurality of TSVs 118 (e.g., 118A, 118M) that provide electrical connections (via respective bump bonds 152 (e.g., 152A, 152M), for example) between portions of respective channels of the plurality of electrical channels formed on the ASIC chip 130 and portions of the respective channels of the plurality of electrical channels formed on the confinement apparatus chip 110.

In an example embodiment, the confinement apparatus chip 110 may include one or more functional layers 116. For example, the one or more functional layers 116 are disposed between the confinement apparatus die 112 and the plurality of electrodes 114, in an example embodiment, and include electrical components (e.g., capacitors such as shunt capacitors and/or trench capacitors, modulators, signal splitters, signal combiners, signal filters, integrated circuits configured to generate microwave fields or signals, and/or the like), optical components (e.g., waveguides, couplers, gratings, metasurfaces, refractive and/or diffractive optics, multiplexers, demultiplexers, beam splitters, beam combiners, modulators, amplifiers, lasers, and/or the like), dielectric components (e.g., for electrically and/or optically isolating the plurality of electrodes and/or other components of the confinement apparatus, and/or the like), and/or other functional components. For example, in an example embodiment, the one or more functional layers 116 include shunt capacitors that are coupled to and/or part of respective channels of the plurality of electrical channels.

In various embodiments, the plurality of electrodes 114 define a confinement apparatus 102. As shown, the confinement apparatus package 100 comprises a confinement apparatus 102 that is coupled with an ASIC 132. In various embodiments, the confinement apparatus 102 is a surface confinement apparatus (e.g., a surface ion trap) that defines a confinement plane 103 that is substantially parallel to a plane of the exposed surface of the plurality of electrodes 114.

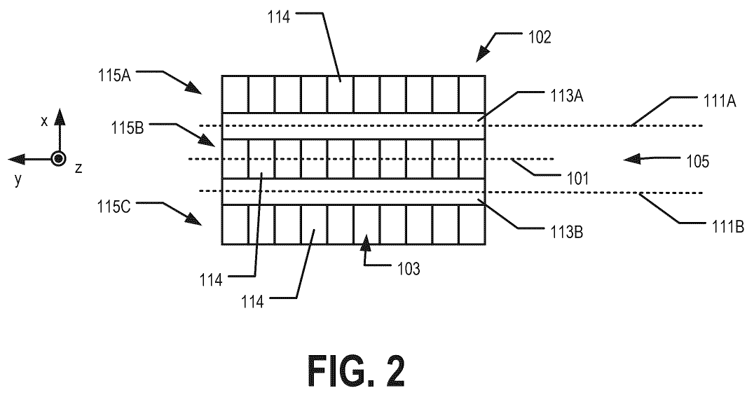

FIG. 2 shows a top view of an example portion of a confinement apparatus 102. In an example embodiment, the example confinement apparatus 102 is at least partially defined by a number of radio frequency (RF) rails 113 (e.g., 113A, 113B) and a number of sequences of electrodes 115 (e.g., 115A, 115B, 115C). In various embodiments, each sequence of electrodes 115 comprises a respective plurality of electrodes 114. In an example embodiment, the confinement apparatus 102 is a surface Paul ion trap with symmetric sequences of electrodes. In various embodiments the electrodes 114 are configured to have voltage signals applied thereto to cause the formation of and/or control the depth and/or location of one or more potential wells configured to trap and/or confine atomic objects, and/or the like. In various embodiments, the upper surface of the confinement apparatus 102 has a planarized topology.

In various embodiments, the RF rails 113 are formed with substantially parallel longitudinal axes 111 (e.g., 111A, 111B) and with substantially coplanar upper surfaces. For example, as shown, the RF rails 113 are substantially parallel such that a distance between the RF rails 113 is approximately constant along the length of the RF rails 113. For example, the upper surfaces of the RF rails 113 may be substantially flush with the upper surface of the confinement apparatus 102. In various embodiments, the confinement apparatus 102 may comprise a plurality of RF rails 113. For example, the confinement apparatus 102 may be a two-dimensional confinement apparatus that comprises multiple numbers (e.g., pairs and/or sets) of RF rails 113 with each number (e.g., pair and/or set) of lengths of RF rails 113 having substantially parallel longitudinal axes. FIG. 2 illustrates an example one-dimensional portion of a confinement apparatus 102 having two RF rails 113, though other embodiments may comprise additional RF rails in various configurations.

In various embodiments, two adjacent RF rails 113 are separated (e.g., insulated) from one another by a gap 105. For example, the gap defines (in one or two dimensions) the confinement channel or region of the confinement apparatus 102 in which one or more atomic objects (e.g., ions, atom, molecules, and/or the like) may be trapped at various locations within the confinement apparatus 102. In various embodiments, the gap 105 defined by the adjacent RF rails 113 extends substantially parallel to the longitudinal axes 111 of the adjacent RF rails 113. For example, the gap 105 may extend substantially parallel to the y-axis. In an example embodiment, the gap 105 is at least partially filled with an insulating material (e.g., a dielectric material). In various embodiments, the dielectric material is silicon dioxide (e.g., formed through thermal oxidation) and/or other dielectric and/or insulating material. In various embodiments, the longitudinal gap 105 has a height (e.g., in the x-direction, as illustrated in FIG. 2) of approximately 40 μm to 500 μm. In various embodiments, one or more sequences of electrodes 115 (e.g., a second sequence of control electrodes 115B) may be disposed and/or formed within the gap 105. In an example embodiment, the gap 105 between neighboring and/or adjacent RF rails 113 is in the range of approximately 1-10 μm.

In an example embodiment, a number (e.g., pair) of RF rails 113 are formed between a first sequence of electrodes 115A and a third sequence of electrodes 115C with a second sequence of electrodes 115B extends along the longitudinal gap 105 between the RF rails 113. For example, in an example embodiment, each sequence of electrodes 115 extends in a direction substantially parallel to the longitudinal axes of the RF rails 113 (e.g., in the y-direction). In various embodiments, the upper surfaces of the sequences of electrodes 115 are substantially coplanar with the upper surfaces of the RF rails 113.

In various embodiments, RF signals may be applied to the RF rails to generate an electric and/or magnetic field that acts to maintain, trap, and/or confine one or more atomic objects. In various embodiments, voltage signals are applied to the electrodes 114 to generate a time-dependent electric potential field that causes the atomic objects trapped and/or confined by the confinement apparatus 102 to traverse corresponding trajectories to perform various transportation functions. In various embodiments, the number of sequences of electrodes 115 may, in combination, be biased, with voltages that contribute to a variable combined electrical and/or magnetic field to confine at least one atomic object in a potential well above at least one of either an upper surface of the sequences of electrodes 115 and/or the RF rails 113 (e.g., in the confinement plane 103). For example, the electrical and/or magnetic field generated at least in part by voltage signals applied to the electrodes 114 may confine at least one atomic object in a potential well above the upper surface of the second sequence of control electrodes 115B and/or the gap 105. Additionally, the voltage signals applied to the electrodes 114 may cause atomic object confined within the potential well above the upper surface of the second sequence of electrodes 115B and/or the longitudinal gap 105 to traverse trajectories such that one or more transportation functions are performed.

In various embodiments, the RF rails 113, the sequences of electrodes 115, and/or the confinement potential generated by application of voltage signals to the RF rails 113 and/or electrodes 114 of the sequences of electrodes 115 define a confinement plane 103 of the confinement apparatus 102. In various embodiments, the RF rails 113, the sequences of electrodes 115, and/or the confinement potential generated by application of voltage signals to the RF rails 113 and/or electrodes 114 of the sequences of electrodes 115 define an axis 101 of the confinement apparatus 102. In an example embodiment, the RF null of the confinement apparatus (e.g., the null line of the pseudopotential generated by the application of the RF voltage signal to the RF rails 113) is substantially parallel to the axis 101 and located within the confinement plane 103. For example, the atomic objects confined by the confinement apparatus 102 are generally disposed at respective locations along the axis 101.

In various embodiments, the atomic objects trapped and/or confined by the confinement apparatus 102 experience a confinement potential generated by application of respective voltage signals to the RF rails 113 and the electrodes 114 (e.g., via respective channels of the plurality of electrical channels defined by the ASIC 132). In various embodiments, the confinement potential (e.g., a pseudopotential) generally acts to align the atomic objects confined by the confinement apparatus 102 within the longitudinal gap 105 and/or along the axis 101. For example, the confinement potential may be generally tube and/or cigar shaped to confine the atomic objects within the longitudinal gap 105 and/or along axis 101, in an example embodiment.

In various embodiments, the voltage signals are applied to the electrodes 114 via respective channels of the plurality of electrical channels defined, at least in part, by the ASIC 132. For example, in various embodiments, the ASIC 132 (formed on the ASIC chip 130) is configured to receive a first set of voltage signals from the package substrate 140, split and/or combine various voltage signals of the first set of voltage signals to form a second set of voltage signals, control and/or condition one or more respective aspects (e.g., amplitude, phase, noise profile (e.g., via filtering), and/or the like) of respective voltage signals of the second set of voltage signals. Respective voltage signals of the second set of voltage signals are provided via respective channels of the plurality of electrical channels such that the voltage signals are applied to respective electrodes 114 of the confinement apparatus chip 110.

In various embodiments, the package substrate 140, ASIC chip 130, and confinement apparatus chip 110 are fabricated individually. For example, the package substrate 140, ASIC chip 130, and confinement apparatus chip 110 may be fabricated via respective fabrication processes appropriate for the components of the respective chips.

The chips may then be packaged together such that the package substrate 140, ASIC chip 130, and confinement apparatus chip 110 are coupled to one another. For example, the chips may then be packaged together such that the package substrate 140, ASIC chip 130, and confinement apparatus chip 110 are mechanically coupled to one another. For example, the chips may then be packaged together such that the package substrate 140, ASIC chip 130, and confinement apparatus chip 110 are electrically coupled to one another. For example, the wire bonds 150 and/or other electrical connections between the package substrate 140 and the ASIC chip 130 may be formed, soldered into place, and/or the like. In another example, bump bonds 152 and/or other surface connections may be formed between the ASIC chip 130 and the TSVs 118 of the confinement apparatus chip 110. For example, a first portion of a respective channel of the plurality of electrical channels is housed by the ASIC chip 130 and a second portion of the respective channel of the plurality of electrical channels is housed by the confinement apparatus chip 110, in an example embodiment. The ASIC chip 130 and the confinement apparatus chip 110 are electrically coupled such that the first portion of the respective channel and the second portion of the respective channel are in electrical communication with one another.

In various embodiments, the ASIC chip 130 and the package substrate 140 may be configured and/or sized to enable room for the wire bonds 150. For example, the ASIC chip 130 may have a larger surface area than the confinement apparatus chip 110 such that a peripheral portion of the surface of the ASIC chip 130 is available for wired connections (e.g., wire bonds 150) with the package substrate 140. For example, the package substrate 140 may have a larger surface area than the ASIC chip 130 such that a peripheral portion of the surface of the package substrate 140 is available for wired connections (e.g., wire bonds 150) with the ASIC chip 130.

In various embodiments, the confinement apparatus chip 110, ASIC chip 130, and package substrate 140 are configured to be in electrical communication with a common ground. In various embodiments, the confinement apparatus chip 110, ASIC chip 130, and package substrate are electrically isolated from one another other than the connections between respective portions of the respective channels of the plurality of electrical channels (e.g., via wire bonds 150, bump bonds 152, TSVs 118, and/or the like).

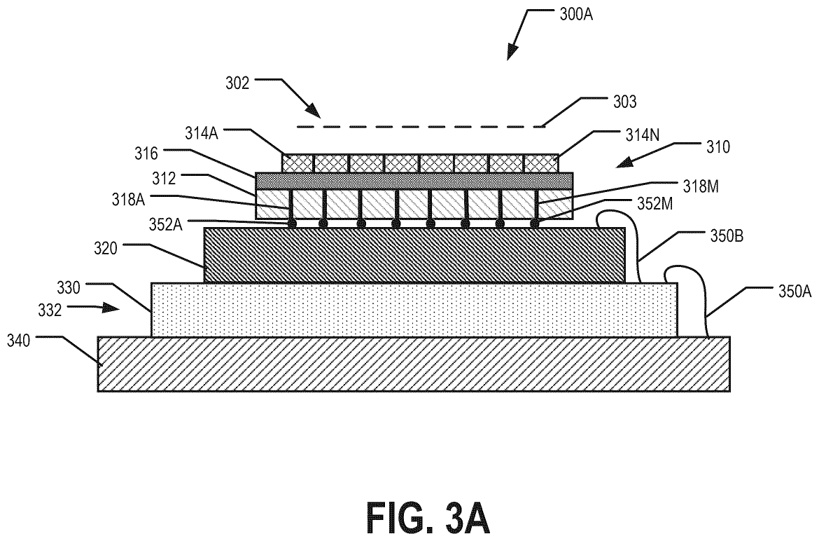

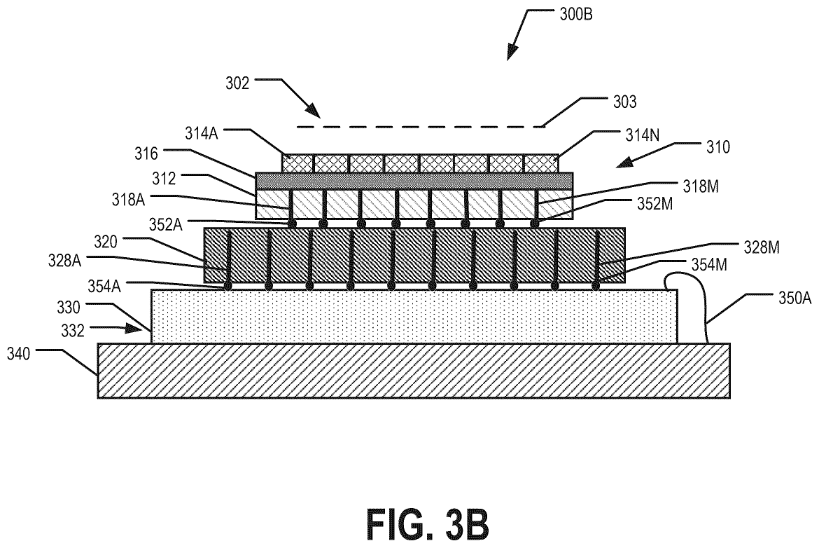

FIG. 3A illustrates another example confinement apparatus package 300A. FIG. 3B illustrates another example confinement apparatus package 300B. The confinement apparatus package 300A includes a confinement apparatus chip 310, an interposer chip 320, an ASIC chip 330, and a package substrate 340. The confinement apparatus package 300A is package such that the ASIC chip 330 is disposed between the package substrate 340 and the interposer chip 320 and the interposer chip 320 is disposed between the ASIC chip 330 and the confinement apparatus chip 310.

In various embodiments, the package substrate 340 is a ceramic package, printed circuit board, and/or the like. In various embodiments, the package substrate 340 is configured to act as a handle of the confinement apparatus package 300A. In various embodiments, the package substrate 340 is configured to receive a plurality of electrical and/or voltage signals that were generated externally (e.g., by voltage sources 50 in FIG. 6). The package substrate 340 may receive the plurality of electrical and/or voltage signals via edge wire bonds, through-silicon-vias (TSVs), and/or the like. In an example embodiment, the package substrate 340 is configured to be mounted in a seat or socket configured to align electrical connection points of the package substrate 340 with electrical connection points of the seat or socket such that the externally generated electrical signals and/or voltage signal are provided to the package substrate 340.

In various embodiments, the ASIC chip 330 comprises an ASIC 332. The ASIC includes electrical components arranged in circuit portions configured to perform application-specific functions. In an example embodiment, the electrical components of the ASIC include capacitors such as shunt capacitors and/or trench capacitors, modulators, signal splitters, signal combiners, amplifiers, phase control elements, delay elements, and/or the like. In an example embodiment, the ASIC 332 formed on the ASIC chip 330 includes shunt capacitors that are coupled to and/or part of respective channels of the plurality of electrical channels.

In various embodiments, the ASIC 332 defines a plurality of electrical channels. For example, the ASIC receives electrical and/or voltage signals from the package substrate 340 via a plurality of wire bonds 350A. The ASIC 332 may split and/or combine the received electrical and/or voltage signals to generate channel-specific electrical and/or voltage signals to be provided to respective channels of the plurality of electrical channels. The ASIC 332 may then condition one or more respective aspects (e.g., amplitude, phase, noise profile (e.g., via filtering), and/or the like) of the channel-specific electrical and/or voltage signal of each respective channel of the plurality of electrical channels.

In various embodiments, the interposer chip 320 is configured to be an electrical interface for routing the voltage signals of the respective channels of the plurality of electrical channels from the first portion of the respective channel formed on the ASIC chip 330 to the second portion of the respective channel formed on the confinement apparatus chip 310 via a third portion of the respective channel formed on the interposer chip 320. In an example embodiment, one or more shunt capacitors may be housed by the interposer chip 320. For example, in an example embodiment, the third portion of the respective channel formed on the interposer chip 320 may include a shunt capacitor.

In various embodiments, the third portion of the respective channel formed on the interposer chip 320 is in electrical communication with a first portion of the respective channel formed on the ASIC chip 330. For example, in FIG. 3A, a third portion of the respective channel formed on the interposer chip 320 is in electrical communication with a first portion of the respective channel formed on the ASIC chip 330 via a respective wire bond 350B. For example, in FIG. 3B, a third portion of the respective channel formed on the interposer chip 320 is in electrical communication with a first portion of the respective channel formed on the ASIC chip 330 via a respective TSV 328 (e.g., 328A, 328M) formed through at least a portion of the interposer chip 320 and a respective bump bond 354 (e.g., 354A, 354M) or other surface connector.

In various embodiments, shunt capacitors that are coupled to and/or part of respective channels of the plurality of electrical channels. In an example embodiment, each of the shunt capacitors of a respective channel of the plurality of electrical channels is formed on the interposer chip 320.

In various embodiments, the third portion of the respective channel formed on the interposer chip 320 is in electrical communication with a second portion of the respective channel formed on the confinement apparatus chip 310. For example, a third portion of the respective channel formed on the interposer chip 320 is in electrical communication with a second portion of the respective channel formed on the confinement apparatus chip 310 via a respective TSV 318 (e.g., 318A, 318M) formed through confinement apparatus die 312 and a respective bump bond 352 (e.g., 352A, 352M) or other surface connector.

For example, the confinement apparatus chip 310 comprises a confinement apparatus die 312 and a plurality of electrodes 314 (e.g., 314A, 314N) formed thereon. Each of the plurality of electrodes 314 of the confinement apparatus chip 310 are in communication with a respective channel of the plurality of electrical channels. For example, in various embodiments, the confinement apparatus die 312 includes a plurality of TSVs 318 that provide electrical connections (via respective bump bonds 352, for example) between portions of respective channels of the plurality of electrical channels formed on the interposer chip 320 and portions of the respective channels of the plurality of electrical channels formed on the confinement apparatus chip 310.

In an example embodiment, the confinement apparatus chip 310 may include one or more functional layers 316. For example, the one or more functional layers 316 are disposed between the confinement apparatus die 312 and the plurality of electrodes 314, in an example embodiment, and include electrical components (e.g., capacitors such as shunt capacitors and/or trench capacitors, modulators, signal splitters, signal combiners, signal filters, integrated circuits configured to generate microwave fields or signals, and/or the like), optical components (e.g., waveguides, couplers, gratings, metasurfaces, refractive and/or diffractive optics, multiplexers, demultiplexers, beam splitters, beam combiners, modulators, amplifiers, lasers, and/or the like), dielectric components (e.g., for electrically and/or optically isolating the plurality of electrodes and/or other components of the confinement apparatus, and/or the like), and/or other functional components. For example, in an example embodiment, the one or more functional layers 316 include shunt capacitors that are coupled to and/or part of respective channels of the plurality of electrical channels.

In various embodiments, the plurality of electrodes 314 define a confinement apparatus 302. As shown, the confinement apparatus package 300A, 300B comprises a confinement apparatus 302 that is coupled with an ASIC 332 via the interposer chip 320. In various embodiments, the confinement apparatus 302 is a surface confinement apparatus (e.g., a surface ion trap) that defines a trapping plane 303 that is substantially parallel to a plane of the exposed surface of the plurality of electrodes 314.

For example, the confinement apparatus 302 may be similar to the confinement apparatus 102, in various embodiments. For example, in various embodiments, the confinement apparatus 302 is defined at least in part by one or more pairs of substantially parallel RF rails and a plurality of electrodes 314.

In various embodiments, the voltage signals are applied to the electrodes 314 via respective channels of the plurality of electrical channels defined, at least in part, by the ASIC 332. For example, in various embodiments, the ASIC 332 (formed on the ASIC chip 330) is configured to receive a first set of voltage signals from the package substrate 340, split and/or combine various voltage signals of the first set of voltage signals to form a second set of voltage signals, control and/or condition one or more respective aspects (e.g., amplitude, phase, noise profile (e.g., via filtering), and/or the like) of respective voltage signals of the second set of voltage signals. For example, the ASIC 332 may include a plurality of (analog) switches, multiplexers, demultiplexers, digital to analog converters (DACs), analog to digital converters (ADCs), shunt capacitors, and/or the like configured to form the second set of voltage signals from the first set of voltage signals. For example, the ASIC 332 may include one or more amplitude and/or phase modulators, amplifiers, filters, and/or the like to control and/or condition one or more respective aspects of respective voltage signals of the second set of voltage signals. Respective voltage signals of the second set of voltage signals are provided via respective channels of the plurality of electrical channels (e.g., via the interposer chip 320) such that the voltage signals are applied to respective electrodes 314 of the confinement apparatus chip 310.

In various embodiments, the package substrate 340, ASIC chip 330, and/or interposer chip 320 includes thermal and/or heat slugs. In various embodiments, the thermal and/or heat slugs are formed of a thermally conductive material (e.g., silver, copper, gold, aluminum nitride, silicon carbide, aluminum, tungsten, graphite, zinc, and/or the like). The thermal and/or heat slugs are configured to conduct heat generated through operation of the ASIC 332 away from the confinement apparatus chip 310.

In various embodiments, the package substrate 340, ASIC chip 330, interposer chip 320, and confinement apparatus chip 310 are fabricated individually. For example, the package substrate 340, ASIC chip 330, interposer chip 320, and confinement apparatus chip 310 may be fabricated via respective fabrication processes appropriate for the components of the respective chips.

The chips may then be packaged together such that the package substrate 340, ASIC chip 330, interposer chip 320, and confinement apparatus chip 310 are coupled to one another. For example, the chips may then be packaged together such that the package substrate 340, ASIC chip 330, interposer chip 320, and confinement apparatus chip 310 are mechanically coupled to one another. For example, the chips may then be packaged together such that the package substrate 340, ASIC chip 330, interposer chip 320, and confinement apparatus chip 310 are electrically coupled to one another. For example, the wire bonds 350A and/or other electrical connections between the package substrate 340 and the ASIC chip 330 may be formed, soldered into place, and/or the like. For example, the wire bonds 350B and/or other electrical connections between the ASIC chip 330 and the interposer chip 320 may be formed, soldered into place, and/or the like. In another example, bump bonds 354 and/or other surface connections may be formed between the ASIC chip 330 and the TSVs 328 of the interposer chip 320. In another example, bump bonds 352 and/or other surface connections may be formed between the interposer chip 320 and the TSVs 318 of the confinement apparatus chip 110. For example, a first portion of a respective channel of the plurality of electrical channels is housed by the ASIC chip 330, a second portion of the respective channel of the plurality of electrical channels is housed by the confinement apparatus chip 310, and a third portion of the respective channel of the plurality of electrical channels is housed by the interposer chip 320, in an example embodiment. The ASIC chip 330 and the interposer chip 320 are electrically coupled to such that first portion of the respective channel and third portion of the respective channel are in electrical communication with one another. The interposer chip 320 and the confinement apparatus chip 310 are electrically coupled such that the third portion of the respective channel and the second portion of the respective channel are in electrical communication with one another.

In various embodiments, the interposer chip 320, ASIC chip 330, and/or the package substrate 340 may be configured and/or sized to enable room for the wire bonds 350A, 350B. For example, the interposer chip 320 may have a larger surface area than the confinement apparatus chip 310 such that a peripheral portion of the surface of the interposer chip 320 is available for wired connections (e.g., wire bonds 350B) with the ASIC chip 330. For example, the ASIC chip 330 may have a larger surface area than the interposer chip 320 such that a peripheral portion of the surface of the ASIC chip 330 is available for wired connections (e.g., wire bonds 350A, 350B) with the package substrate 340 and/or interposer chip 320. For example, the package substrate 340 may have a larger surface area than the ASIC chip 330 such that a peripheral portion of the surface of the package substrate 340 is available for wired connections (e.g., wire bonds 350A) with the ASIC chip 330.

In various embodiments, the confinement apparatus chip 310, interposer chip 320, ASIC chip 330, and package substrate 340 are configured to be in electrical communication with a common ground. In various embodiments, the confinement apparatus chip 310, interposer chip 320, ASIC chip 330, and package substrate 340 are electrically isolated from one another other than the connections between respective portions of the respective channels of the plurality of electrical channels (e.g., via wire bonds 350A, bump bonds 352, 354, TSVs 318, 328, and/or the like).

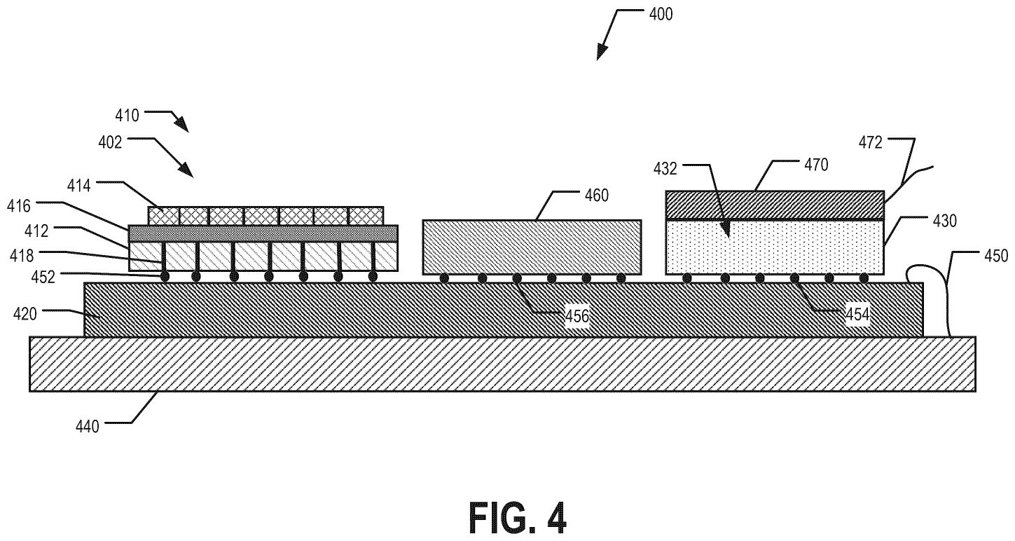

FIG. 4 illustrates another example confinement apparatus package 400. The confinement apparatus package 400 has a 2.5D architecture. In various embodiments, the confinement apparatus package 400 includes a confinement apparatus chip 410, an interposer chip 420, an ASIC chip 430, and a package substrate 440. The confinement apparatus package 400 is package such that the interposer chip 420 is disposed between the package substrate 440 and both the confinement apparatus chip 410 and the ASIC chip 430. For example, the confinement apparatus chip 410 and the ASIC chip 430 are laterally arranged with respect to one another.

In an example embodiment, the confinement apparatus package 400 further includes a shunt capacitor chip 460. In various embodiments, the shunt capacitor chip comprises a plurality of shunt capacitors formed on a shunt capacitor die. The interposer chip 420 is disposed between the shunt capacitor chip 460 and the package substrate 440. For example, the shunt capacitor chip 460 is laterally arranged with respect to the confinement apparatus chip 410 and the ASIC chip 430.

In various embodiments, the package substrate 440 is a ceramic package, printed circuit board, and/or the like. In various embodiments, the package substrate 440 is configured to act as a handle of the confinement apparatus package 400. In various embodiments, the package substrate 440 is configured to receive a plurality of electrical and/or voltage signals that were generated externally (e.g., by voltage sources 50 in FIG. 6). The package substrate 440 may receive the plurality of electrical and/or voltage signals via edge wire bonds, through-silicon-vias (TSVs), and/or the like. In an example embodiment, the package substrate 440 is configured to be mounted in a seat or socket configured to align electrical connection points of the package substrate 440 with electrical connection points of the seat or socket such that the externally generated electrical signals and/or voltage signal are provided to the package substrate 440.

In various embodiments, the ASIC chip 430 comprises an ASIC 432. The ASIC includes electrical components arranged in circuit portions configured to perform application-specific functions. In an example embodiment, the electrical components of the ASIC include capacitors such as shunt capacitors and/or trench capacitors, modulators, signal splitters, signal combiners, amplifiers, phase control elements, delay elements, and/or the like. In an example embodiment, the ASIC 432 formed on the ASIC chip 430 includes shunt capacitors that are coupled to and/or part of respective channels of the plurality of electrical channels.

In various embodiments, the ASIC 432 defines a plurality of electrical channels. For example, the ASIC receives electrical and/or voltage signals from the package substrate 440 via the interposer chip 420. The ASIC 432 may split and/or combine various ones of the received electrical and/or voltage signals to generate channel-specific electrical and/or voltage signals to be provided to respective channels of the plurality of electrical channels. The ASIC 432 may then condition one or more respective aspects (e.g., amplitude, phase, noise profile (e.g., via filtering), and/or the like) of the channel-specific electrical and/or voltage signal of each respective channel of the plurality of electrical channels.

In various embodiments, the ASIC chip 430 is flip chip mounted to the interposer chip 420 (e.g., via bump bonds 454). For example, the ASIC chip 430 is mechanically mounted to the interposer chip 420 in a flip chip configuration via bump bonds 454, in an example embodiment. For example, first portions of respective channels of the plurality of electrical channels housed by the ASIC chip 430 are in electrical communication with third portions of the respective channels housed by the interposer chip 420 via bump bonds 454, in an example embodiment.

In the illustrated embodiment, a backside cooler 470 is operatively connected to ASIC chip 430. For example, the backside cooler 470 is secured to the exposed back surface of the ASIC chip 430, in an example embodiment. In various embodiments, the backside cooler 470 is configured to cool the ASIC chip 430 such that heat generated by operation of the ASIC 432 does not impact operation of the confinement apparatus 402. In an example embodiment, electrical leads 472 are configured to be in electrical communication with a power source to provide power to the backside cooler 470.

In various embodiments, the interposer chip 420 is configured to be an electrical interface for routing the voltage signals of the respective channels of the plurality of electrical channels from the first portion of the respective channel formed on the ASIC chip 430 to the second portion of the respective channel formed on the confinement apparatus chip 410 via third portions of the respective channel formed on the interposer chip 420. In an example embodiment, the interposer chip 420 is configured to be an electrical interface for routing the voltage signals of the respective channels of the plurality of electrical channels from the first portion of the respective channel formed on the ASIC chip 430 to the second portion of the respective channel formed on the confinement apparatus chip 410 via third portions of the respective channel formed on the interposer chip 420 and a forth portion of the respective channel formed on the shunt capacitor chip 460.

For example, the interposer chip 420 may receive electrical and/or voltage signals from the package substrate 440 and provide the electrical and/or voltage signals to the ASIC chip 430. The ASIC 432 formed on the ASIC chip 430 generates channel-specific electrical and/or voltage signals from the electrical and/or voltage signals and conditioning and/or controlling various aspects thereof. The ASIC chip 430 provides the channel-specific electrical and/or voltage signals to the interposer chip 420.

The interposer chip 420 provides the channel-specific electrical and/or voltage signals to the shunt capacitor chip 460 such that charge injection and/or electrical transients present in the channel-specific electrical and/or voltage signals are mitigated and/or dampened. The shunt capacitor chip 460 provides the transient-dampened channel-specific electrical and/or voltage signals to the interposer chip 420. The interposer chip 420 then provides the transient-dampened channel-specific electrical and/or voltage signals to the confinement apparatus chip 410. The transient-dampened channel-specific electrical and/or voltage signals are then applied to one or more electrodes 414 associated with the respective channel to control operation of the confinement apparatus 402.

In various embodiments, each of the respective channels of the plurality of electrical channels includes at least one shunt capacitor. In an example embodiment, each of the shunt capacitors of a respective channel of the plurality of electrical channels is formed on the shunt capacitor chip 460. In various embodiments, the shunt capacitor chip 460 is flip chip mounted to the interposer chip 420 (e.g., via bump bonds 456). For example, the shunt capacitor chip 460 is mechanically mounted to the interposer chip 420 in a flip chip configuration via bump bonds 456, in an example embodiment. For example, forth portions of respective channels of the plurality of electrical channels housed by the shunt capacitor chip 460 are in electrical communication with third portions of the respective channels housed by the interposer chip 420 via bump bonds 456, in an example embodiment. In an example embodiment, one or more capacitors of the plurality of shunt capacitors formed on the shunt capacitor chip 460 are trench capacitors. In an example embodiment, one or more capacitors of the plurality of shunt capacitors are plate capacitors, metal-insulator-metal (MIM) capacitors, and/or other types of capacitors. In an example embodiment, each of the one or more capacitors has a capacitance in a range of 5 to 5000 pF. For example, in an example embodiment, each of the one or more capacitors has a capacitance of 100 pF.

In various embodiments, the third portion of the respective channel formed on the interposer chip 420 is in electrical communication with a second portion of the respective channel formed on the confinement apparatus chip 410. For example, a third portion of the respective channel formed on the interposer chip 420 is in electrical communication with a second portion of the respective channel formed on the confinement apparatus chip 410 via a respective TSV 418 formed through confinement apparatus die 412 and a respective bump bond 452 or other surface connector.

For example, the confinement apparatus chip 410 comprises a confinement apparatus die 412 and a plurality of electrodes 414 formed thereon. Each of the plurality of electrodes 414 of the confinement apparatus chip 410 are in communication with a respective channel of the plurality of electrical channels. For example, in various embodiments, the confinement apparatus die 412 includes a plurality of TSVs 418 that provide electrical connections (via respective bump bonds 452, for example) between portions of respective channels of the plurality of electrical channels formed on the interposer chip 420 and portions of the respective channels of the plurality of electrical channels formed on the confinement apparatus chip 410.

In an example embodiment, the confinement apparatus chip 410 may include one or more functional layers 416. For example, the one or more functional layers 416 are disposed between the confinement apparatus die 412 and the plurality of electrodes 414, in an example embodiment, and include electrical components (e.g., capacitors such as shunt capacitors and/or trench capacitors, modulators, signal splitters, signal combiners, signal filters, integrated circuits configured to generate microwave fields or signals, and/or the like), optical components (e.g., waveguides, couplers, gratings, metasurfaces, refractive and/or diffractive optics, multiplexers, demultiplexers, beam splitters, beam combiners, modulators, amplifiers, lasers, and/or the like), dielectric components (e.g., for electrically and/or optically isolating the plurality of electrodes and/or other components of the confinement apparatus, and/or the like), and/or other functional components. For example, in an example embodiment, the one or more functional layers 416 include shunt capacitors that are coupled to and/or part of respective channels of the plurality of electrical channels.

In various embodiments, the plurality of electrodes 414 define a confinement apparatus 402. As shown, the confinement apparatus package 400 comprises a confinement apparatus 402 that is coupled with an ASIC 432 via the interposer chip 420 (and the shunt capacitor chip 460). In various embodiments, the confinement apparatus 402 is a surface confinement apparatus (e.g., a surface ion trap) that defines a trapping plane 403 that is substantially parallel to a plane of the exposed surface of the plurality of electrodes 414.

For example, the confinement apparatus 402 may be similar to the confinement apparatus 102, in various embodiments. For example, in various embodiments, the confinement apparatus 402 is defined at least in part by one or more pairs of substantially parallel RF rails and a plurality of electrodes 414.

In various embodiments, the voltage signals are applied to the electrodes 414 via respective channels of the plurality of electrical channels defined, at least in part, by the ASIC 432. For example, in various embodiments, the ASIC 432 (formed on the ASIC chip 430) is configured to receive a first set of voltage signals from the package substrate 440 (via the interposer chip 420), split and/or combine various voltage signals of the first set of voltage signals to form a second set of voltage signals, control and/or condition one or more respective aspects (e.g., amplitude, phase, noise profile (e.g., via filtering), and/or the like) of respective voltage signals of the second set of voltage signals. Respective voltage signals of the second set of voltage signals are provided via respective channels of the plurality of electrical channels (e.g., via the interposer chip 420 and/or the shunt capacitor chip 460) such that the voltage signals are applied to respective electrodes 414 of the confinement apparatus chip 410.

In various embodiments, the package substrate 440, ASIC chip 430, the shunt capacitor chip 460, and/or interposer chip 420 includes thermal and/or heat slugs. In various embodiments, the thermal and/or heat slugs are formed of a thermally conductive material (e.g., silver, copper, gold, aluminum nitride, silicon carbide, aluminum, tungsten, graphite, zinc, and/or the like). The thermal and/or heat slugs are configured to conduct heat generated through operation of the ASIC 432 away from the confinement apparatus chip 410.

In various embodiments, the package substrate 440, ASIC chip 430, interposer chip 420, shunt capacitor chip 460, and confinement apparatus chip 410 are fabricated individually. For example, the package substrate 440, ASIC chip 430, interposer chip 420, shunt capacitor chip 460, and confinement apparatus chip 410 may be fabricated via respective fabrication processes appropriate for the components of the respective chips.

The chips may then be packaged together such that the package substrate 440, ASIC chip 430, interposer chip 420, shunt capacitor chip 460, and confinement apparatus chip 410 are coupled to one another. For example, the chips may then be packaged together such that the interposer chip 420 is mechanically coupled to the package substrate 340 such that preliminary portions of respective channels of the plurality of electrical channels housed on the package substrate are in electrical communication with respective third portions of the respective channels housed by the interposer chip 420 (e.g., via wire bonds 450). For example, the ASIC chip 430 and/or the shunt capacitor chip 460 are flip chip mounted to the interposer chip 420. For example, the ASIC chip 430 and/or the shunt capacitor chip 460 are mechanically coupled to the interposer chip 420 via bump bonds 454, 456, in an example embodiment. For example, respective portions of respective channels housed on the ASIC chip 430 and/or the shunt capacitor chip 460 are in electrical communication with respective portions of the respective channels housed by the interposer chip 420 via bump bonds 454, 456, in an example embodiment. In another example, bump bonds 452 and/or other surface connections may be formed between the interposer chip 420 and the TSVs 418 of the confinement apparatus chip 410 such that the confinement apparatus chip 410 is mechanically coupled to the interposer chip 420. For example, the interposer chip 420 and the confinement apparatus chip 410 are electrically coupled such that the third portion of the respective channel housed by the interposer chip 420 and the second portion of the respective channel housed by the confinement apparatus chip 410 are in electrical communication with one another.

In various embodiments, the interposer chip 420, and/or the package substrate 440 are configured and/or sized to enable room for the wire bonds 450. For example, the interposer chip 420 may have a larger surface area than the combined surface area of the confinement apparatus chip 410, ASIC chip 430, and shunt capacitor chip 460 such that a peripheral portion of the surface of the interposer chip 420 is available for wired connections (e.g., wire bonds 450) with the package substrate 440. For example, the package substrate 440 may have a larger surface area than the interposer chip 420 such that a peripheral portion of the surface of the package substrate 440 is available for wired connections (e.g., wire bonds 450) with the interposer chip 420.

In various embodiments, the confinement apparatus chip 410, interposer chip 420, shunt capacitor chip 460, ASIC chip 430, and package substrate 440 are configured to be in electrical communication with a common ground. In various embodiments, the confinement apparatus chip 410, interposer chip 420, ASIC chip 430, shunt capacitor chip 460, and package substrate 440 are electrically isolated from one another other than the connections between respective portions of the respective channels of the plurality of electrical channels (e.g., via wire bonds 450, bump bonds 452, 454, 456, TSVs 418, and/or the like).

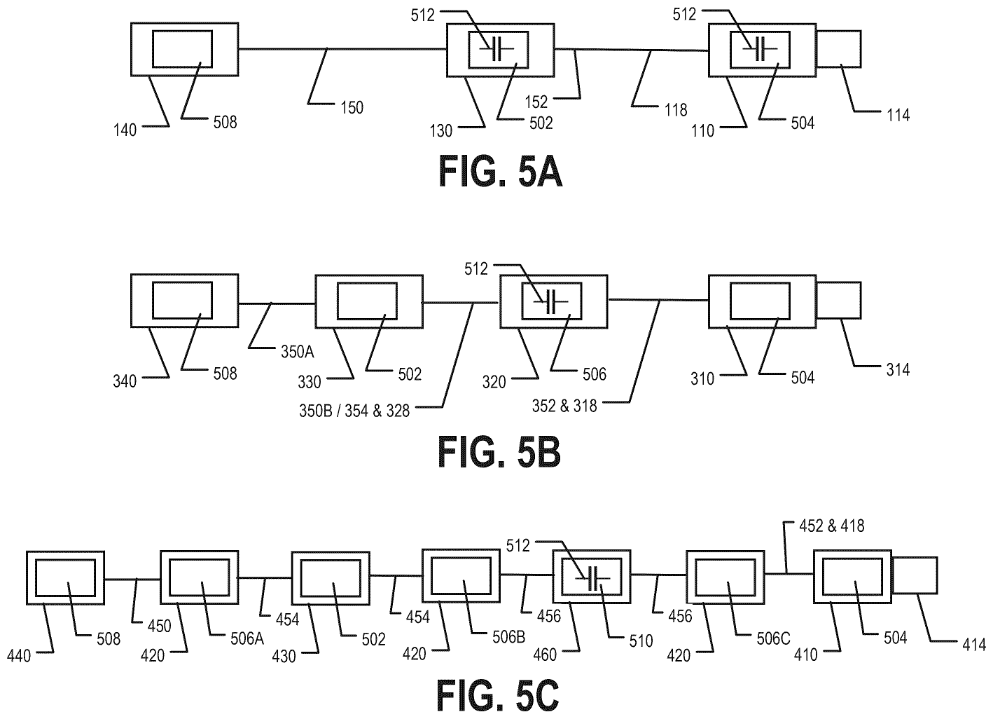

FIG. 5A provides a schematic diagram of a respective channel of the plurality of electrical channels for the example confinement apparatus package 100. For example, a preliminary portion 508 of the respective channel is housed by the package substrate 140. In an example embodiment, a respective preliminary portion 508 is part of more than one respective channel. For example, a preliminary portion 508 may provide an electrical and/or voltage signal that is then split by the ASIC 132 into multiple channel-specific electrical and/or voltage signals that are provided to respective channels.

The preliminary portion 508 of the respective channel is in electrical communication with a first portion 502 of the respective channel housed by the ASIC chip 130 via wire bond 150. The first portion 502 of the respective channel is configured to condition and/or control one or more aspects of the channel-specific electrical and/or voltage signal. For example, the first portion 502 may be configured to control and/or condition the amplitude, phase, noise profile (e.g., via filtering), and/or other aspect of the channel-specific electrical and/or voltage signal provided via the respective channel.

In an example embodiment, the first portion 502 includes one or more shunt capacitors 512. For example, the first portion 502 may include a switch and the one or more shunt capacitors 512 are positioned in the respective channel between the switch and the one or more electrodes 114 associated with the respective channel.

In an example embodiment, the first portion 502 of the respective channel is in electrical communication with a second portion 504 of the respective channel housed by the confinement apparatus chip 110. For example, the first portion 502 and the second portion 504 of the respective channel are in electrical communication via bump bonds 152 and vias 118, in an example embodiment. In an example embodiment, the second portion 504 of the respective channel includes one or more shunt capacitors 512. The respective channel provides the channel-specific electrical and/or voltage signal to one or more electrodes 114 associated with and/or in electrical communication with the respective channel.

FIG. 5B provides a schematic diagram of a respective channel of the plurality of electrical channels for the example confinement apparatus package 300A, 300B. For example, a preliminary portion 508 of the respective channel is housed by the package substrate 340. In an example embodiment, a respective preliminary portion 508 is part of more than one respective channel. For example, a preliminary portion 508 may provide an electrical and/or voltage signal that is then split by the ASIC 332 into multiple channel-specific electrical and/or voltage signals that are provided to respective channels.

The preliminary portion 508 of the respective channel is in electrical communication with a first portion 502 of the respective channel housed by the ASIC chip 330 via wire bond 350A. The first portion 502 of the respective channel is configured to condition and/or control one or more aspects of the channel-specific electrical and/or voltage signal. For example, the first portion 502 may be configured to control and/or condition the amplitude, phase, noise profile (e.g., via filtering), and/or other aspect of the channel-specific electrical and/or voltage signal provided via the respective channel.

In an example embodiment, the first portion 502 of the respective channel is in electrical communication with a third portion 506 of the respective channel housed by the interposer chip 320. In various embodiments, the first portion 502 and the third portion 506 of the respective channel are in electrical communication with one another via wire bond 350B or via a bump bond 352 and via 328. In an example embodiment, the third portion 506 includes one or more shunt capacitors 512. For example, the first portion 502 of the respective channel may include a switch and the one or more shunt capacitors 512 are positioned in the respective channel between the switch and the one or more electrodes 314 associated with the respective channel.

In an example embodiment, the third portion 506 of the respective channel is in electrical communication with a second portion 504 of the respective channel housed by the confinement apparatus chip 310. For example, the third portion 506 and the second portion 504 of the respective channel are in electrical communication via bump bonds 352 and vias 318, in an example embodiment. In an example embodiment, the second portion 504 of the respective channel includes one or more shunt capacitors 512. The respective channel provides the channel-specific electrical and/or voltage signal to one or more electrodes 314 associated with and/or in electrical communication with the respective channel.

FIG. 5C provides a schematic diagram of a respective channel of the plurality of electrical channels for the example confinement apparatus package 400. For example, a preliminary portion 508 of the respective channel is housed by the package substrate 440. In an example embodiment, a respective preliminary portion 508 is part of more than one respective channel. For example, a preliminary portion 508 may provide an electrical and/or voltage signal that is then split by the ASIC 432 into multiple channel-specific electrical and/or voltage signals that are provided to respective channels.

The preliminary portion 508 of the respective channel is in electrical communication with part A of third portion 506A of the respective channel housed by the interposer chip 420. For example, the preliminary portion 508 may be in electrical communication with part A of the third portion 506A via a wire bond 450. Part A of the third portion 506A of the respective channel is in electrical communication with a first portion 502 of the respective channel housed by the ASIC chip 530 via bump bonds 454. The first portion 502 of the respective channel is configured to condition and/or control one or more aspects of the channel-specific electrical and/or voltage signal. For example, the first portion 502 may be configured to control and/or condition the amplitude, phase, noise profile (e.g., via filtering), and/or other aspect of the channel-specific electrical and/or voltage signal provided via the respective channel.

In an example embodiment, the first portion 502 of the respective channel is in electrical communication with part B of the third portion 506B of the respective channel housed by the interposer chip 320. In various embodiments, the first portion 502 and part B of the third portion 506B of the respective channel are in electrical communication with one another via bump bond 454.

In an example embodiment, part B of the third portion 506B of the respective channel is in electrical communication with a fourth portion 510 of the respective channel housed by the shunt capacitor chip 460. In an example embodiment, part B of the third portion 506B of the respective channel is in electrical communication with the fourth portion 510 of the respective channel via bump bonds 456. In an example embodiment, the fourth portion of the respective channel includes one or more shunt capacitors 512. For example, the first portion 502 of the respective channel may include a switch and the one or more shunt capacitors 512 are positioned in the respective channel between the switch and the one or more electrodes 414 associated with the respective channel.

In an example embodiment that does not include a shunt capacitor chip 460, the one or more shunt capacitors 512 may be part of the first portion 502, second portion 504, or third portion (e.g., between the first portion 502 and the second portion 504) of the respective channel.

In an example embodiment, the fourth portion 510 of the respective channel is in electrical communication with part C of the third portion 506C of the respective channel housed by the interposer chip 420. For example, the fourth portion 510 is in electrical communication with part C of the third portion 506C via bump bonds 456, in an example embodiment.

In an example embodiment, part C of the third portion 506C of the respective channel is in electrical communication with a second portion 504 of the respective channel housed by the confinement apparatus chip 410. For example, part C of the third portion 506C and the second portion 504 of the respective channel are in electrical communication via bump bond 452 and vias 418 (e.g., a TSV), in an example embodiment. The respective channel provides the channel-specific electrical and/or voltage signal to one or more electrodes 414 associated with and/or in electrical communication with the respective channel.

In various embodiments, one or more of the plurality of channels are dynamic channels. For example, the ASIC 132, 332, 432 may include one or more switches such that which electrodes 114, 314, 414 are in electrical communication with a particular channel may be adjusted during operation of the confinement apparatus 102, 302, 402 via switching of at least one of the one or more switches. In another example, the which of the electrical and/or voltage signals (and/or combinations thereof) provided to a particular channel may be adjusted during operation of the confinement apparatus 102, 302, 402 via switching of at least one of the one or more switches. In another example, the filtering of an electrical and/or voltage signal provided via a particular channel may be adjusted during the operation of the confinement apparatus (e.g., via switching of at least one of the one or more switches).

While FIGS. 1, 3A, 3B, and 4 illustrate example confinement apparatus packages each including one confinement apparatus chip and one ASIC chip, in various embodiments, a confinement apparatus package includes two or more confinement apparatus chips and/or two or more ASIC chips. For example, the respective pluralities of electrodes of the two or more confinement apparatus chips may collectively define a confinement apparatus. For example, an ASIC chip defines electrical channels in electrical communication with respective electrodes of a plurality of confinement apparatus chips, in an example embodiment. In another example, each ASIC chip defines electrical channels in electrical communication with respective electrodes of a respective confinement apparatus chip (e.g., each confinement apparatus chip may be associated with and/or electrically coupled to a corresponding ASIC chip). In various embodiments, the confinement apparatus package includes two or more interposer chips. The two or more interposer chips may each be electrically coupled to a single ASIC chip and confinement apparatus chip or to multiple ASIC chips and/or confinement apparatus chips, in various embodiments. In an example embodiment, the confinement apparatus package includes two or more shunt capacitor chips.

In various embodiments, a respective ASIC of a respective ASIC chip is configured to define a plurality of electrical channels which are in electrical communication with the respective plurality of electrodes of a respective confinement apparatus, possibly via a respective interposer chip and/or possibly a respective shunt capacitor chip. In various embodiments, a respective ASIC of a respective ASIC chip is configured to define a plurality of electrical channels which are in electrical communication with electrodes of multiple confinement apparatus chips, possibly via one or more interposer chips and/or one or more shunt capacitor chips. For example, the confinement apparatus package may have a modular architecture or an integrated architecture, in various embodiments.

### Example System Including a Confinement Apparatus Package

FIG. 6 provides a schematic diagram of an example system including a confinement apparatus package. The example system illustrated in FIG. 6 is a QCCD-based quantum computer system 600 comprising a confinement apparatus package 100, 300A, 300B, 400, in accordance with an example embodiment. In various embodiments, the quantum computer system 600 comprises a computing entity 10 and a quantum computer 610. In various embodiments, the quantum computer 610 comprises a controller 30, a cryogenic and/or vacuum chamber 40 enclosing a confinement apparatus package 100, 300A, 300B, 400, and one or more manipulation sources 60. In an example embodiment, the one or more manipulation sources 60 may comprise one or more lasers (e.g., optical lasers, microwave sources, and/or the like). In various embodiments, the one or more manipulation sources 60 are configured to manipulate and/or cause a controlled quantum state evolution of one or more atomic objects trapped and/or confined by the confinement apparatus 102, 302, 402 of the confinement apparatus package 100, 300A, 300B, 400. For example, in an example embodiment, wherein the one or more manipulation sources 60 comprise one or more lasers, the lasers may provide one or more laser beams, 66A, 66B, 66C to respective locations of the confinement apparatus 102, 302, 402 within the cryogenic and/or vacuum chamber 40. In various embodiments, the quantum computer 610 comprises one or more voltage sources 50. For example, the voltage sources 50 may comprise a plurality of DC voltage drivers and/or voltage sources and/or at least one RF driver and/or voltage source. For example, the voltage sources 50 may include arbitrary waveform generators (AWGs), digital-analog converters (DACs), and/or the like. The voltage sources 50 may be electrically coupled to the corresponding electrodes and/or RF rails of the confinement apparatus 102, 302, 402. For example, a voltage sources 50 may generate a first set of voltage signals that are provided to a package substrate 140, 340, 440. The package substrate may provide the first set of voltage signals to an ASIC 132, 332, 432 that splits and/or combines the voltage signals of the first set of voltage signals into voltage signals of a second set of voltage signals, where each voltage signal of the second set of voltage signals is provided to one or more electrodes 114, 314, 414 via a respective channel of a plurality of electrical channels defined, at least in part, by the ASIC 132, 332, 432.

In various embodiments, a computing entity 10 is configured to allow a user to provide input to the quantum computer 610 (e.g., via a user interface of the computing entity 10) and receive, view, and/or the like output from the quantum computer 610. The computing entity 10 may be in communication with, coupled and/or connected to the controller 30 of the quantum computer 610 via one or more wired or wireless networks 20 and/or via direct wired and/or wireless communications. In an example embodiment, the computing entity 10 may translate, configure, format, and/or the like information/data, quantum computing algorithms, and/or the like into a computing language, executable instructions, command sets, and/or the like that the controller 30 can understand and/or implement.

In various embodiments, the controller 30 is configured to control the voltage sources 50, cryogenic system and/or vacuum system controlling the temperature and pressure within the cryogenic and/or vacuum chamber 40, manipulation sources 60, and/or other systems controlling various environmental conditions (e.g., temperature, pressure, and/or the like) within the cryogenic and/or vacuum chamber 40 and/or configured to manipulate and/or cause a controlled evolution of quantum states of one or more atomic object trapped and/or confined by the confinement apparatus 102, 302, 402 of the confinement apparatus package 100, 300A, 300B, 400.

In various embodiments, the controller 30 may control one or more components of the ASIC 132, 332, 432. For example, the controller 30 may control a state of one or more switches of respective channels of the plurality of electrical channels where the switches are part of circuit portions formed on the ASIC chip 130, 330, 430. For example, the controller 30 may be electrically coupled to the ASIC 132, 332, 432 such that the control components (e.g., switches) of the ASIC 132, 332, 432 control and/or condition voltage signals (e.g., generated by the voltages sources 50) applied to the control electrodes 114, 314, via respective channels of the plurality of electrical channels defined, at least in part, by the ASIC 132, 332, 432. In various embodiments the state of the one or more switches is controlled by a controller of a system including the confinement apparatus package 100, 300A, 300B, 400.

In various embodiments, at least some of the atomic objects trapped and/or confined by the confinement apparatus 102, 302, 402 are used as qubits of the quantum computer 610.

### Technical Advantages

In various embodiments, the confinement apparatus includes a large number of electrodes and/or electrical channels. In systems including conventional confinement apparatuses, the controlling and/or conditioning of the electrical and/or voltage signals provided the electrodes of the confinement apparatus are performed outside of the cryogenic and/or vacuum chamber, resulting in a large number of electrical and/or voltage signals that need to be passed through the housing of the cryogenic and/or vacuum chamber. Additionally, providing electrical connections for the large number of wire bonds required to connect the large number of electrical and/or voltage signals to the respective electrodes requires a significant amount of space on the chip housing the confinement apparatus. Therefore, technical problems exist regarding how to control, condition, and provide electrical and/or voltage signals to electrodes of a confinement apparatus. These technical problems are particularly challenging for large confinement apparatuses (e.g., configured to trap and/or confine 100 atomic objects or more). For example, a large confinement apparatus may include eight thousand electrodes or more.

Various embodiments provide technical solutions to these technical challenges. Various embodiments provide confinement apparatus packages that include an ASIC chip and a confinement apparatus chip. The ASIC chip comprises circuit portions configured to control and/or condition the electrical and/or voltage signals provided to the electrodes of the confinement apparatus. In various embodiments, the ASIC chip defines a plurality of electrical channels with each electrode of the confinement apparatus in electrical communication with a respective electrical channel of the plurality of electrical channels. In various embodiments, the plurality of electrical channels defined by the ASIC chip is a first number of electrical channels and the ASIC chip is configured to receive a second number of electrical and/or voltage signals.

The ASIC provides appropriate electrical and/or voltage signals to respective electrodes via respective ones of the first number of electrical channels based on the received second number of electrical and/or voltage signals, where the first number is greater than the second number. For example, in an example embodiment, the confinement apparatus comprises eight thousand electrodes. However, providing eight thousand independent electrical and/or voltage signals to the interior of a cryogenic and/or vacuum chamber would be technically complicated. Moreover, the surface area of a confinement apparatus package needed to connect eight thousand electrical connections to the confinement apparatus package would be quite large and would lead to additional technical challenges. Various embodiments provide technical solutions to such technical problems by configuring the ASIC to split a received electrical and/or voltage signal (e.g., received via a package substrate in an example embodiment) and cause independently conditioned versions of the split electrical and/or voltage signals to respective electrodes in electrical communication with respective electrical channels. An example of independently conditioning versions of a split electrical and/or voltage signal in an electrical channel specific manner is described by U.S. Application No. 63,583,629, filed Sep. 19, 2023, the contents of which are incorporated herein by reference. Thus, the ASIC chip enables fewer electrical and/or voltage signals to be passed through the housing of the cryogenic and/or vacuum chamber while enabling individual control of the electric and/or voltage signals provided to respective electrodes via the respective electrical channels. Various embodiments therefore provide improvements to the technical fields of confinement apparatus control and/or operation and systems including confinement apparatuses.

In various scenarios, including the controlling and/or conditioning circuit portions of the ASIC results in additional technical challenges. For example, the controlling and/or conditioning circuit portions of the ASIC may cause charge injection and/or electrical transients to be provided to one or more electrodes of the confinement apparatus that are in electrical communication with a respective electrical channel. In various embodiments, this technical challenge is addressed through the inclusion of shunt capacitors in the respective electrical channels.

An additional technical challenge introduced by including the controlling and/or conditioning circuit portions of the ASIC in close proximity to the confinement apparatus chip is the heating caused by operation of the ASIC. In various embodiments, thermal and/or heat slugs are disposed in the ASIC chip, interposer chip, and/or package substrate to transport heat generated by the operation of the ASIC away from the confinement apparatus chip. In another example, the ASIC chip is flip chip mounted to an interposer chip such that a backside cooler can be operatively secured to the backside of the ASIC chip. Therefore, various embodiments provide technical solutions to technical problems that arise in the inclusion the ASIC chip in the confinement apparatus package.

### Example Controller

In various embodiments, the confinement apparatus package 100, 300A, 300B, 400 is incorporated into a QCCD-based quantum computer. In various embodiments, a quantum computer further comprises a controller configured to control various elements of the quantum computer. For example, the controller may be configured to control operation of the voltage sources, a cryogenic system and/or vacuum system controlling the temperature and pressure within the cryogenic and/or vacuum chamber, manipulation sources, and/or other systems controlling the environmental conditions (e.g., temperature, humidity, pressure, and/or the like) within the cryogenic and/or vacuum chamber and/or configured to manipulate and/or cause a controlled evolution of quantum states of one or more atomic object confined by the confinement apparatus 102, 302, 402.

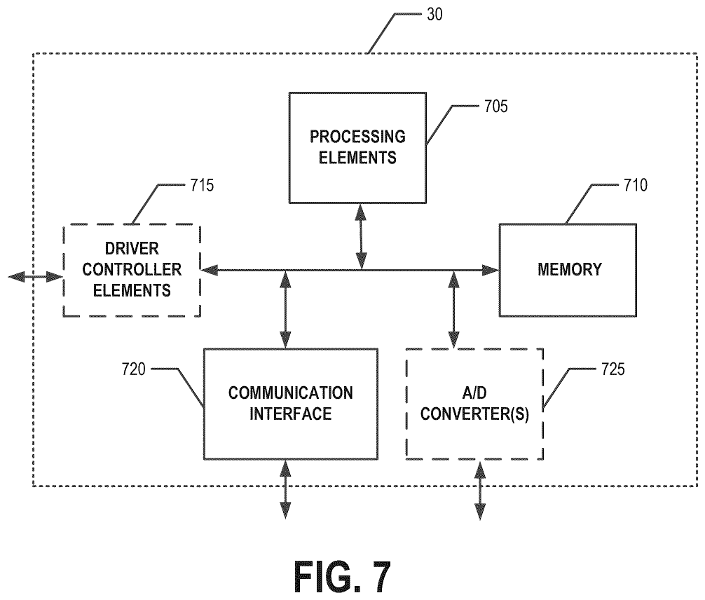

As shown in FIG. 7, in various embodiments, the controller 30 may comprise various controller elements including processing elements 705, memory 710, driver controller elements 715, a communication interface 720, analog-digital converter elements 725, and/or the like. For example, the processing elements 705 may comprise programmable logic devices (CPLDs), microprocessors, coprocessing entities, application-specific instruction-set processors (ASIPs), integrated circuits, application specific integrated circuits (ASICs), field programmable gate arrays (FPGAs), programmable logic arrays (PLAs), hardware accelerators, other processing devices and/or circuitry, and/or the like. and/or controllers. The term circuitry may refer to an entirely hardware embodiment or a combination of hardware and computer program products. In an example embodiment, the processing element 705 of the controller 30 comprises a clock and/or is in communication with a clock.

For example, the memory 710 may comprise non-transitory memory such as volatile and/or non-volatile memory storage. In various embodiments, the memory 710 may store qubit records corresponding the qubits of quantum computer (e.g., in a qubit record data store, qubit record database, qubit record table, and/or the like), a calibration table, an executable queue, computer program code (e.g., in a one or more computer languages, specialized controller language(s), and/or the like), and/or the like. In an example embodiment, execution of at least a portion of the computer program code stored in the memory 710 (e.g., by a processing element 705) causes the controller 30 to perform one or more steps, operations, processes, procedures and/or the like described herein for applying controlled and/or conditioned sequences of voltages to the DC electrodes of the ion trap apparatus.

In various embodiments, the driver controller elements 715 may include one or more drivers and/or controller elements each configured to control one or more drivers. In various embodiments, the driver controller elements 715 may comprise drivers and/or driver controllers. For example, the driver controllers may be configured to cause one or more corresponding drivers to be operated in accordance with executable instructions, commands, and/or the like scheduled and executed by the controller 30 (e.g., by the processing element 705). In various embodiments, the driver controller elements 715 may enable the controller 30 to operate a manipulation source 60. In various embodiments, the drivers may be laser drivers; vacuum component drivers; drivers for controlling the flow of current and/or voltage applied to RF rails and/or electrodes of the confinement apparatus 102, 302, 402; drivers for optically and/or electronically controlling one or more switches the ASIC 132, 332, 432; cryogenic and/or vacuum system component drivers; and/or the like. For example, the drivers may control and/or comprise DC and/or RF voltage drivers and/or voltage sources that provide voltages and/or electrical signals to the electrodes and/or RF rails of the confinement apparatus.

In various embodiments, the controller 30 comprises means for communicating and/or receiving signals from one or more optical receiver components such as cameras, MEMs cameras, CCD cameras, photodiodes, photomultiplier tubes, and/or the like. For example, the controller 30 may comprise one or more analog-digital converter elements 725 configured to receive signals from one or more optical receiver components, calibration sensors, and/or the like.

In various embodiments, the controller 30 may comprise a communication interface 720 for interfacing and/or communicating with a computing entity 10. For example, the controller 30 may comprise a communication interface 720 for receiving executable instructions, command sets, and/or the like from the computing entity 10 and providing output received from the quantum computer 610 (e.g., from an optical collection system) and/or the result of a processing the output to the computing entity 10. In various embodiments, the computing entity 10 and the controller 30 may communicate via a direct wired and/or wireless connection and/or one or more wired and/or wireless networks 20.

### Example Computing Entity

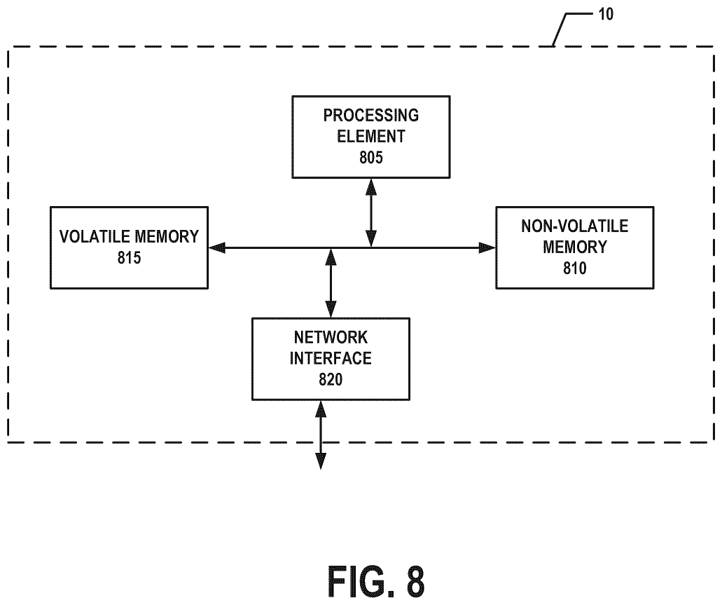

FIG. 8 provides an illustrative schematic representation of an example computing entity 10 that can be used in conjunction with embodiments of the present invention. In various embodiments, a computing entity 10 is configured to allow a user to provide input to the quantum computer 610 (e.g., via a user interface of the computing entity 10) and receive, display, analyze, and/or the like output from the quantum computer 610.

In general, the terms computing entity, computer, entity, device, system, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

As shown in FIG. 8, the computing entity 10 may also include one or more network interfaces 820 for communicating with various computing entities, such as by communicating data, content, information, and/or similar terms used herein interchangeably that can be transmitted, received, operated on, processed, displayed, stored, and/or the like.

In some embodiments, the computing entity 10 may include or be in communication with one or more processing elements 805 (also referred to as processors, processing circuitry, and/or similar terms used herein interchangeably) that communicate with other elements within the computing entity 10 via a bus, for example. As will be understood, the processing element 805 may be embodied in a number of different ways.

As will therefore be understood, the processing element 805 may be configured for a particular use or configured to execute instructions stored in volatile or non-volatile media or otherwise accessible to the processing element 805. As such, whether configured by hardware or computer program products, or by a combination thereof, the processing element 805 may be capable of performing steps or operations according to embodiments of the present invention when configured accordingly.

In one embodiment, computing entity 10 may further include or be in communication with non-volatile media (also referred to as non-volatile storage, memory, memory storage, memory circuitry and/or similar terms used herein interchangeably). In one embodiment, the non-volatile storage or memory may include one or more non-volatile storage or memory media 810. As will be recognized, the non-volatile storage or memory media may store databases, database instances, database management systems, data, applications, programs, program modules, scripts, source code, object code, byte code, compiled code, interpreted code, machine code, executable instructions, and/or the like.

In one embodiment, the computing entity 10 may further include or be in communication with volatile media (also referred to as volatile storage, memory, memory storage, memory circuitry and/or similar terms used herein interchangeably). In one embodiment, the volatile storage or memory may also include one or more volatile storage or memory media 815. As will be recognized, the volatile storage or memory media may be used to store at least portions of the databases, database instances, database management systems, data, applications, programs, program modules, scripts, source code, object code, byte code, compiled code, interpreted code, machine code, executable instructions, and/or the like being executed by, for example, the processing element 805. Thus, the databases, database instances, database management systems, data, applications, programs, program modules, scripts, source code, object code, byte code, compiled code, interpreted code, machine code, executable instructions, and/or the like may be used to control certain aspects of the operation of the computing entity 10 with the assistance of the processing element 805 and operating system.

As indicated, in one embodiment, the computing entity 10 may also include one or more network interfaces 820 for communicating with various computing entities, such as by communicating data, content, information, and/or similar terms used herein interchangeably that can be transmitted, received, operated on, processed, displayed, stored, and/or the like. Similarly, the computing entity 10 may be configured to communicate via wireless client communication networks using any of a variety of protocols.

Although not shown, the computing entity 10 may include or be in communication with one or more input elements, such as a keyboard input, a mouse input, a touch screen/display input, motion input, movement input, audio input, pointing device input, joystick input, keypad input, and/or the like. The computing entity 10 may also include or be in communication with one or more output elements (not shown), such as audio output, video output, screen/display output, motion output, movement output, and/or the like.

### Conclusion

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A confinement apparatus package comprising:
one or more confinement apparatus dies having a respective plurality of electrodes formed thereon, wherein the respective plurality of electrodes defines a confinement apparatus;
one or more application-specific integrated circuit (ASIC) chips comprising a respective ASIC die having a respective ASIC formed thereon; and
a package substrate,
wherein:
the respective ASIC die is disposed between the package substrate and the respective confinement apparatus die, and
the respective ASIC defines a plurality of electrical channels and each electrode of the respective plurality of electrodes is in electrical communication with a respective electrical channel of the plurality of electrical channels.

2. The confinement apparatus package of claim 1, wherein the respective electrical channel comprises at least one shunt capacitor.

3. The confinement apparatus package of claim 2, wherein the at least one shunt capacitor is a trench capacitor.

4. The confinement apparatus package of claim 2, wherein the at least one shunt capacitor is formed one on of (a) the respective confinement apparatus die or (b) the respective ASIC chip.

5. The confinement apparatus package of claim 1, wherein a first portion of the respective electrical channel disposed on the respective ASIC chip is in electrical communication with a second portion of the respective electrical channel disposed on the respective confinement apparatus die, at least in part, via one of (a) a through silicon via (TSV) formed in the respective confinement apparatus die or (b) a wire bond.

6. The confinement apparatus package of claim 1, further comprising one or more interposer chips, a respective interposer chip disposed between the respective ASIC chip and the respective confinement apparatus die.

7. The confinement apparatus package of claim 6, wherein the respective electrical channel comprises at least one shunt capacitor and the at least one shunt capacitor is formed on the respective interposer chip.

8. The confinement apparatus package of claim 6, wherein a first portion of the respective electrical channel disposed on the respective ASIC chip is in electrical communication with a third portion of the respective electrical channel disposed on the respective interposer chip, at least in part, via one of (a) a through silicon via (TSV) formed in an interposer die of the respective interposer chip or (b) a wire bond.

9. The confinement apparatus package of claim 6, wherein a third portion of the respective electrical channel disposed on the respective interposer chip is in electrical communication with a second portion of the respective electrical channel disposed on the respective confinement apparatus die, at least in part, via one of (a) a through silicon via (TSV) formed in the respective confinement apparatus die of the respective confinement apparatus chip or (b) a wire bond.

10. The confinement apparatus package of claim 1, wherein a first portion of the respective electrical channel disposed on the respective ASIC chip is configured to condition a voltage signal applied to one or more electrodes of the respective plurality of electrodes in electrical communication with the respective electrical channel.

11. The confinement apparatus package of claim 1, wherein the package substrate is at least one of a ceramic package or a printed circuit board.

12. The confinement apparatus package of claim 1, wherein a first portion of the respective electrical channel disposed on the respective ASIC chip is in electrical communication with a preliminary portion of the respective electrical channel disposed on the package substrate.

13. The confinement apparatus package of claim 1, wherein the confinement apparatus is a surface ion trap.

14. A confinement apparatus package comprising:
one or more confinement apparatus dies each having a respective plurality of electrodes formed thereon, wherein the respective plurality of electrodes defines a confinement apparatus;
one or more ASIC chips each comprising a respective application-specific integrated circuit (ASIC) die having a respective ASIC formed thereon;
at least one interposer chip; and
a package substrate,
wherein:
the at least one interposer chip is disposed between the respective ASIC die and the package substrate,
the at least one interposer chip is disposed between the respective confinement apparatus die and the package substrate, and
the respective ASIC defines a plurality of electrical channels and each electrode of the respective plurality of electrodes is in electrical communication with a respective electrical channel of the plurality of electrical channels.

15. The confinement apparatus package of claim 14, wherein the respective confinement apparatus die and the respective ASIC chip are laterally arranged with respect to one another.

16. The confinement apparatus package of claim 15, further comprising one or more shunt capacitor chips each comprising a respective plurality of shunt capacitors formed on a respective shunt capacitor die, wherein the at least one interposer chip is disposed between the respective shunt capacitor chip and the package substrate.

17. The confinement apparatus package of claim 16, wherein each shunt capacitor of the respective plurality of shunt capacitors is part of a respective channel of the plurality of electrical channels.

18. The confinement apparatus package of claim 17, wherein at least one shunt capacitor of the respective plurality of shunt capacitors is a trench capacitor.

19. The confinement apparatus package of claim 17, wherein each of the respective confinement apparatus die, the respective ASIC chip, and the respective shunt capacitor chip are laterally arranged with respect to one another.

20. The confinement apparatus package of claim 17, wherein the respective shunt capacitor chip is flip chip mounted to the at least one interposer chip.

21. The confinement apparatus package of claim 15, wherein the respective ASIC chip is flip chip mounted to the at least one interposer chip.

22. The confinement apparatus package of claim 21, further comprising a backside cooler disposed on an exposed surface of the respective ASIC die, wherein the backside cooler is configured to cool the respective ASIC chip.

23. The confinement apparatus package of claim 17, wherein a first portion of the respective electrical channel disposed on the respective ASIC chip is in electrical communication with a third portion of the respective electrical channel disposed on the respective shunt capacitor chip via the at least one interposer chip.

24. The confinement apparatus package of claim 17, wherein a third portion of the respective electrical channel disposed on the respective shunt capacitor chip is in electrical communication with a second portion of the respective electrical channel disposed on the respective confinement apparatus die, at least in part, via at least one of (a) the respective interposer chip or (b) a through-silicon-via (TSV) formed in the respective confinement apparatus die.

25. The confinement apparatus package of claim 14, wherein a first portion of the respective electrical channel disposed on the respective ASIC chip is in electrical communication with a second portion of the respective electrical channel disposed on the respective confinement apparatus die, at least in part, via a through silicon via (TSV) formed in the respective confinement apparatus die.

26. The confinement apparatus package of claim 14, wherein a first portion of the respective electrical channel disposed on the respective ASIC chip is configured to condition a voltage signal applied to one or more electrodes of the respective plurality of electrodes in electrical communication with the respective electrical channel.

27. The confinement apparatus package of claim 14, wherein the package substrate is at least one of a ceramic package or a printed circuit board.

28. The confinement apparatus package of claim 14, wherein a first portion of the respective electrical channel disposed on the respective ASIC die is in electrical communication a preliminary portion of the respective electrical channel disposed on the package substrate.

29. The confinement apparatus package of claim 14, wherein the confinement apparatus is a surface ion trap.
